(19) United States
(12) Patent Application Publication
(10) Pub. No.: US 2026/0289879 A1
(43) Pub. Date: Sep. 24, 2026

(54) IMAGE PROCESSING DEVICE AND IMAGE PROCESSING METHOD

(71) Applicant: HAMAMATSU PHOTONICS K.K., Hamamatsu-shi, Shizuoka (JP)

(72) Inventor: Fumio HASHIMOTO, Gainesville, FL (US)

(73) Assignee: HAMAMATSU PHOTONICS K.K., Hamamatsu-shi, Shizuoka (JP)

(21) Appl. No.: 19/476,466

(22) PCT Filed: Mar. 18, 2024
(86) PCT No.: PCT/JP2024/010568

§ 371 Date: Oct. 17, 2025

(30) Foreign Application Priority Data
Apr. 25, 2023 (JP) 2023-071331

(51) Int. Cl. G06T 12/30; G01T 1/29

(52) U.S. Cl. CPC G06T 12/30; G01T 1/2985; G06T 2207/20081; G06T 2207/20084

(57) ABSTRACT

An image processing apparatus includes a sinogram creation unit, a CNN processing unit, a convolution integration unit, a forward projection calculation unit, a CNN training unit, a storage unit, and an image reconstruction unit. The forward projection calculation unit performs forward projection calculation on an output image to create a calculated sinogram. In a first processing step, the CNN training unit trains a CNN based on an error between a reconstructed image created by the image reconstruction unit and the output image. In a subsequent second processing step, the CNN training unit trains the CNN based on an error between a measured sinogram and the calculated sinogram.

### TECHNICAL FIELD

The present disclosure relates to an apparatus and a method for creating a tomographic image of a subject based on coincidence information collected by using a radiation tomography apparatus.

### BACKGROUND ART

Examples of a radiation tomography apparatus capable of acquiring a tomographic image of a subject (a living body) include a positron emission tomography (PET) apparatus and a single photon emission computed tomography (SPECT) apparatus.

The PET apparatus includes a detection unit having a large number of small radiation detectors arranged around a measurement space in which the subject is placed. The PET apparatus detects a photon pair of an energy of 511 keV generated by electron positron annihilation in the subject into which a positron-emitting isotope (an RI source) is injected by a coincidence method using the detection unit, and collects coincidence information of the detection.

Further, a tomographic image representing a spatial distribution of a generation frequency of the photon pairs in the measurement space (that is, a spatial distribution of the RI sources) can be reconstructed based on the collected many pieces of the coincidence information described above. The above PET apparatus plays an important role in a nuclear medicine field and the like, and can be used to study, for example, a biological function or a brain high-order function.

As a method for reconstructing the tomographic image of the subject based on the collected many pieces of the coincidence information, various methods are known. In an image processing method used for reconstructing the tomographic image which is described in Non Patent Document 1, the tomographic image is reconstructed by a deep image prior technique using a convolutional neural network, which is a type of a deep neural network. Hereinafter, the convolutional neural network is referred to as a “CNN”, and the deep image prior technique is referred to as a “DIP technique”.

The DIP technique takes advantage of the property of the CNN that meaningful structures in an image are learned faster than random noise (that is, the random noise is less likely to be learned). By using the DIP technique, the tomographic image in which the noise is reduced can be acquired.

Specifically, the image processing method described in Non Patent Document 1 is as follows. A sinogram (hereinafter, referred to as a “measured sinogram”) is created based on the many pieces of the coincidence information collected for the subject. Further, a sinogram (hereinafter, referred to as a “calculated sinogram”) is created by performing forward projection calculation (Radon transform) on an image output from the CNN when an input image (for example, an MRI image) is input to the CNN.

Further, an error between the calculated sinogram and the measured sinogram is evaluated, and the CNN is trained based on the error evaluation result. By using the DIP technique, when the image output from the CNN, the creation of the calculated sinogram by the forward projection calculation, the evaluation of the error, and the training of the CNN are repeatedly performed, the calculated sinogram gradually approaches the measured sinogram, and the output image from the CNN approaches the tomographic image of the subject.

The above image processing method includes a process of performing the forward projection from the CNN output image to the calculated sinogram, and on the other hand, does not include a process of performing back projection from the measured sinogram to the tomographic image, and thus, it is possible to acquire the tomographic image in which the noise is further reduced. Further, in the image processing method described in Non Patent Document 1, each of the measured sinogram and the calculated sinogram is divided into a plurality of blocks, and the error between the calculated sinogram and the measured sinogram is evaluated for each of the blocks to train the CNN, and thus, storage capacity required at the time of performing the processing is reduced.

The sinogram is expressed as a histogram representing a frequency (a generation frequency of coincidence events) at which the coincidence information is acquired in a space (a sinogram space) represented by four variables of r, θ, z, and δ. The variable r represents a position in a radial direction of a coincidence detection line (a line connecting two detectors which perform coincidence detection of the photon pair). The variable θ represents an azimuth angle of the coincidence detection line. The variable z represents a position in a center axis direction of a midpoint of the coincidence detection line. Further, the variable δ represents a polar angle of the coincidence detection line.

### CITATION LIST

### Non Patent Literature

Non Patent Document 1: F. Hashimoto, Y. Onishi, K. Ote, H. Tashima and T. Yamaya, “Fully 3D Implementation of the End-to-end Deep Image Prior-based PET Image Reconstruction Using Block Iterative Algorithm”, arXiv preprint, arXiv: 2212.11844, doi: 10.48550/arXiv.2212.11844, 2022
Non Patent Document 2: J. Nuyts et al., “A concave prior penalizing relative differences for maximum-a-posteriori reconstruction in emission tomography”, IEEE TNS, Vol. 49, Issue 1, pp. 56-60, 2002
Non Patent Document 3: Hiroyuki Kudo, “Image Reconstruction Methods in Low-Dose CT: Fundamentals of Statistical Image Reconstruction, Iterative Image Reconstruction, and Compressed Sensing”, Medical Imaging Technology, Vol. 32, No. 4, pp. 239-248, 2014
Non Patent Document 4: Antonin Chambolle, “An Algorithm for Total Variation Minimization and Applications”, Journal of Mathematical Imaging and Vision 20, pp. 89-97, 2004

### SUMMARY OF INVENTION

### Technical Problem

The image processing method by using the DIP technique described in Non Patent Document 1 has excellent noise reduction performance, and in addition, the method requires a large number of CNN training epochs, and takes time to obtain the tomographic image of the subject in which noise is reduced.

An object of the present invention is to provide an image processing apparatus and an image processing method capable of reducing the number of CNN training epochs by using a DIP technique and obtaining a tomographic image in which noise is reduced in a short time, when creating the tomographic image of a subject by training a CNN based on an evaluation result of an error between a calculated sinogram and a measured sinogram.

### Solution to Problem

An embodiment of the present invention is an image processing apparatus. The image processing apparatus is an image processing apparatus for creating a tomographic image of a subject based on coincidence information collected by a radiation tomography apparatus including a plurality of detectors arranged around a measurement space in which the subject into which an RI source is injected is placed, and includes (1) an image reconstruction unit for creating a reconstructed image by using an analytical image reconstruction method or a statistical image reconstruction method based on the coincidence information collected by the radiation tomography apparatus; (2) a sinogram creation unit for creating a sinogram based on the coincidence information collected by the radiation tomography apparatus; (3) a CNN processing unit for inputting an input image to a convolutional neural network, and creating an output image by the convolutional neural network; (4) a forward projection calculation unit for performing forward projection calculation on the output image to create a sinogram; and (5) a CNN training unit for training the convolutional neural network, and (6) in a first processing step, (a) the CNN training unit uses an evaluation function including an error evaluation term representing an evaluation value related to an error between the reconstructed image and the output image, and trains the convolutional neural network based on a value of the evaluation function, and (b) respective processes of the CNN processing unit and the CNN training unit are repeatedly performed a plurality of times, and (7) in a second processing step following the first processing step, (a) the CNN training unit uses an evaluation function including an error evaluation term representing an evaluation value related to an error between the sinogram created by the sinogram creation unit and the sinogram created by the forward projection calculation unit, and trains the convolutional neural network based on a value of the evaluation function, and (b) the output image after respective processes of the CNN processing unit, the forward projection calculation unit, and the CNN training unit are repeatedly performed a plurality of times is set as the tomographic image of the subject.

An embodiment of the present invention is a radiation tomography system. The radiation tomography system includes a radiation tomography apparatus including a plurality of detectors arranged around a measurement space in which a subject into which an RI source is injected is placed, and for collecting coincidence information; and the image processing apparatus of the above configuration for creating the tomographic image of the subject based on the coincidence information collected by the radiation tomography apparatus.

An embodiment of the present invention is an image processing method. The image processing method is an image processing method for creating a tomographic image of a subject based on coincidence information collected by a radiation tomography apparatus including a plurality of detectors arranged around a measurement space in which the subject into which an RI source is injected is placed, and includes (1) an image reconstruction step of creating a reconstructed image by using an analytical image reconstruction method or a statistical image reconstruction method based on the coincidence information collected by the radiation tomography apparatus; (2) a sinogram creation step of creating a sinogram based on the coincidence information collected by the radiation tomography apparatus; (3) a CNN processing step of inputting an input image to a convolutional neural network, and creating an output image by the convolutional neural network; (4) a forward projection calculation step of performing forward projection calculation on the output image to create a sinogram; and (5) a CNN training step of training the convolutional neural network, and (6) in a first processing step, (a) in the CNN training step, an evaluation function including an error evaluation term representing an evaluation value related to an error between the reconstructed image and the output image is used, and the convolutional neural network is trained based on a value of the evaluation function, and (b) respective processes of the CNN processing step and the CNN training step are repeatedly performed a plurality of times, and (7) in a second processing step following the first processing step, (a) in the CNN training step, an evaluation function including an error evaluation term representing an evaluation value related to an error between the sinogram created in the sinogram creation step and the sinogram created in the forward projection calculation step is used, and the convolutional neural network is trained based on a value of the evaluation function, and (b) the output image after respective processes of the CNN processing step, the forward projection calculation step, and the CNN training step are repeatedly performed a plurality of times is set as the tomographic image of the subject.

### Advantageous Effects of Invention

According to the embodiments of the present invention, it is possible to reduce the number of CNN training epochs by using a DIP technique and obtain a tomographic image in which noise is reduced in a short time, when creating the tomographic image of a subject by training a CNN based on an evaluation result of an error between a calculated sinogram and a measured sinogram.

### BRIEF DESCRIPTION OF DRAWINGS

FIG. 1 is a diagram illustrating a configuration of a radiation tomography system 1.

FIG. 2 is a diagram illustrating a configuration example of a CNN.

FIG. 3 is a flowchart illustrating an image processing method.

FIG. 4 is a flowchart illustrating a first processing step of the image processing method.

FIG. 5 is a flowchart illustrating a second processing step of the image processing method.

FIG. 6 includes diagrams showing respective examples of a calculated sinogram 24 in the case in which block division is not performed and calculated sinograms 24₁ to 24₁₆ in the case in which the block division is performed in comparison with each other, and shows (a) a diagram schematically showing the calculated sinogram 24 in the case in which the block division is not performed, and (b) a diagram schematically showing the calculated sinograms 24₁ to 24₁₆ in the case in which the block division is performed.

FIG. 7 is a diagram for describing adjacent pixels in an output image.

FIG. 8 is a diagram showing an original image (a correct image) of a tomographic image of a brain.

FIG. 9 is a diagram showing the tomographic image of the brain obtained by using a first image processing method.

FIG. 10 is a diagram showing the tomographic image of the brain obtained by using a second image processing method.

### DESCRIPTION OF EMBODIMENTS

Hereinafter, embodiments of an image processing apparatus and an image processing method will be described in detail with reference to the accompanying drawings. In the description of the drawings, the same elements will be denoted by the same reference signs, and redundant description will be omitted. The present invention is not limited to these examples, and the Claims, their equivalents, and all the changes within the scope are intended as would fall within the scope of the present invention.

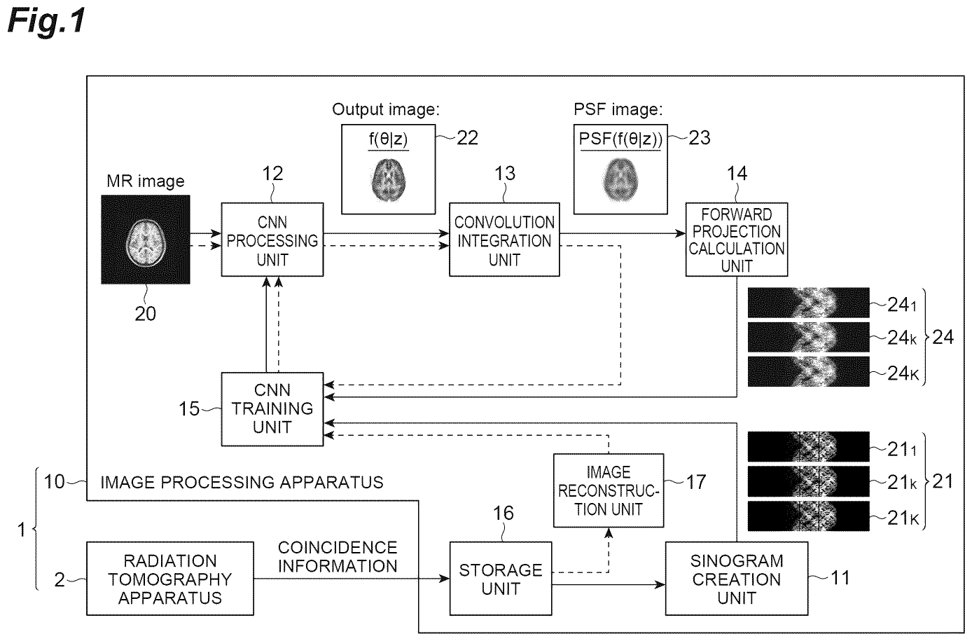

FIG. 1 is a diagram illustrating a configuration of a radiation tomography system 1. The radiation tomography system 1 includes a radiation tomography apparatus 2 and an image processing apparatus 10. The image processing apparatus 10 includes a sinogram creation unit 11, a CNN processing unit 12, a convolution integration unit 13, a forward projection calculation unit 14, a CNN training unit 15, a storage unit 16, and an image reconstruction unit 17.

In addition, each of an input image, a reconstructed image, an output image, and a tomographic image which are used in the image processing apparatus 10 may be a two-dimensional image, or may be a three-dimensional image, and further, in the following description, it is assumed that each of the above images is the three-dimensional image. Further, each of a measured sinogram and a calculated sinogram may be divided into a plurality of blocks, or may not be divided into the plurality of blocks, and further, in the following description, the case in which each of the above sinograms is divided into the plurality of blocks will be mainly described.

The radiation tomography apparatus 2 is an apparatus for collecting coincidence information for reconstructing a tomographic image of a subject. Examples of the radiation tomography apparatus 2 include a PET apparatus and a SPECT apparatus. In the following description, it is assumed that the radiation tomography apparatus 2 is the PET apparatus.

The radiation tomography apparatus 2 includes a detection unit having a large number of small radiation detectors which are arranged around a measurement space in which the subject is placed. The radiation tomography apparatus 2 detects a photon pair of an energy of 511 keV generated by the electron positron annihilation in the subject into which an RI source is injected by a coincidence method by using the detection unit, and collects the coincidence information of the detection. Further, the radiation tomography apparatus 2 outputs the collected coincidence information to the image processing apparatus 10.

The image processing apparatus 10 includes a graphics processing unit (GPU) for performing processing by using a convolutional neural network (CNN), an input unit (for example, a keyboard or a mouse) for receiving an input from an operator, a display unit (for example, a liquid crystal display) for displaying an image and the like, and a storage unit for storing a program and data for executing various types of the processing. As the image processing apparatus 10, for example, a computer including a CPU, a RAM, a ROM, a hard disk drive, and the like is used.

The storage unit 16 inputs and stores the coincidence information collected by the radiation tomography apparatus 2. The image reconstruction unit 17 creates a reconstructed image by using a general image reconstruction method based on the coincidence information stored by the storage unit 16. The general image reconstruction method is not a reconstruction method performed by using a CNN, and the method is an analytical image reconstruction method or a statistical image reconstruction method.

Examples of the analytical image reconstruction method include a filtered back projection (FBP) method, and the like. Examples of the statistical image reconstruction method include techniques such as a maximum likelihood expectation maximization (ML-EM), an ordered subset expectation maximization (OSEM), a row action maximum likelihood algorithm (RAMLA), and a dynamic RAMLA (DRAMA), and the like.

The sinogram creation unit 11 creates a measured sinogram 21 based on the coincidence information stored in the storage unit 16. In this case, the sinogram creation unit 11 creates measured sinograms 21₁ to 21_{K} divided into a plurality of (K) blocks. The measured sinogram 21ₖ is a measured sinogram of the k-th block out of the K blocks. K is an integer of 2 or more, and k is an integer of 1 or more and K or less. The entire measured sinogram 21 is obtained by combining the divided measured sinograms 21₁ to 21_{K}.

The CNN processing unit 12 inputs a three-dimensional input image 20 to the CNN, and creates a three-dimensional output image 22 by the CNN. The three-dimensional input image 20 may be an image representing morphological information of the subject, may be an MRI image, a CT image, or a static PET image of the subject, or may be a random noise image.

The convolution integration unit 13 performs convolution integration of a point spread function on the three-dimensional output image 22 created by the CNN processing unit 12, and creates a new three-dimensional output image 23. The point spread function (PSF) is a function representing a response (impulse response) of the radiation tomography apparatus with respect to a point source, and is in general represented by a Gaussian function, an asymmetric Gaussian function in which the degree of blurring differs depending on a position in a visual field modeled from the measured data of the point source, or the like. By providing the convolution integration unit 13, the tomographic image with more excellent image quality can be obtained, and further, training of the CNN can be stabilized.

The forward projection calculation unit 14 performs forward projection calculation on the three-dimensional output image 23 to create a calculated sinogram 24. In this case, the forward projection calculation unit 14 creates calculated sinograms 24₁ to 24_{K} divided into the K blocks. The calculated sinogram 24ₖ is a calculated sinogram of the k-th block out of the K blocks. The entire calculated sinogram 24 is obtained by combining the divided calculated sinograms 24₁ to 24_{K}.

The block division of the calculated sinogram 24 is performed in the same manner as the block division of the measured sinogram 21. The calculated sinogram 24ₖ of the k-th block and the measured sinogram 21ₖ of the k-th block are the sinograms of a common region in an entire sinogram space. The configuration of the block division is set arbitrary, and the block division may be performed for any one or two or more variables out of the four variables representing the sinogram space. A size of each of the K blocks may be different, or may be the same.

The CNN training unit 15 trains the CNN by the DIP technique using an evaluation function including an error evaluation term different from each other in a first processing step and a second processing step to be described later. In the first processing step, the CNN training unit 15 uses the evaluation function including the error evaluation term representing an evaluation value related to an error between the reconstructed image created by the image reconstruction unit 17 and the output image created by the convolution integration unit 13, and trains the CNN based on the error evaluation result.

In the second processing step, the CNN training unit 15 uses the error function including the error evaluation term representing an evaluation value related to an error between the measured sinogram 21ₖ and the calculated sinogram 24ₖ for each of the K blocks, and trains the CNN based on the error evaluation result for each of the K blocks. The CNN training unit 15 continuously performs the training of the CNN in the second processing step following the training of the CNN in the first processing step.

In the first processing step, the respective processes of the CNN processing unit 12, the convolution integration unit 13, and the CNN training unit 15 are repeatedly performed a plurality of times. A processing flow of the first processing step is indicated by a dashed line arrow in the image processing apparatus 10 illustrated in FIG. 1.

In the second processing step following the first processing step, the respective processes of the CNN processing unit 12, the convolution integration unit 13, the forward projection calculation unit 14, and the CNN training unit 15 are repeatedly performed a plurality of times. A processing flow of the second processing step is indicated by a solid line arrow in the image processing apparatus 10 illustrated in FIG. 1.

Further, the three-dimensional output image 22 which is created by the CNN processing unit 12 is set as a three-dimensional tomographic image of the subject. The three-dimensional output image 23 which is created by the convolution integration unit 13 may be set as the three-dimensional tomographic image of the subject. The measured sinogram 21 is a sinogram reflecting a response function of the radiation tomography apparatus, and thus, it is preferable that the three-dimensional output image 22 before performing the convolution integration of the point spread function by the convolution integration unit 13 is set as the three-dimensional tomographic image of the subject.

In addition, the convolution integration unit 13 may be provided as the final layer of the CNN, or may be provided separately from the CNN. In the case in which the convolution integration unit 13 is provided as the final layer of the CNN, a weight coefficient of the convolution integration unit 13 is maintained constant in the training of the CNN.

Further, the convolution integration unit 13 may not be provided. In the case in which the convolution integration unit 13 is not provided, in the first processing step, the CNN training unit 15 uses the evaluation function including the error evaluation term representing an evaluation value related to an error between the reconstructed image created by the image reconstruction unit 17 and the three-dimensional output image 22 created by the CNN processing unit 12, and trains the CNN based on the error evaluation result. Further, in the case in which the convolution integration unit 13 is not provided, in the second processing step, the forward projection calculation unit 14 performs the forward projection calculation on the three-dimensional output image 22 output from the CNN processing unit 12 to create the calculated sinogram 24.

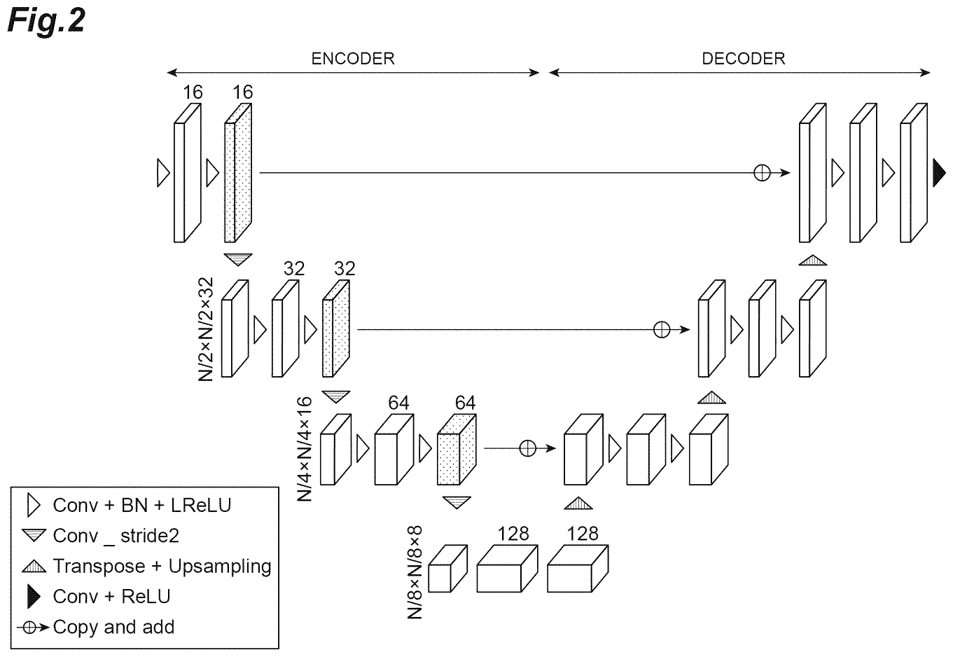

FIG. 2 is a diagram illustrating a configuration example of the CNN. The CNN illustrated in this diagram has a three-dimensional U-net structure including an encoder and a decoder. In this diagram, a size of each of the layers of the CNN is illustrated on the assumption that the number of pixels of the three-dimensional input image 20 which is input to the CNN is N×N×64.

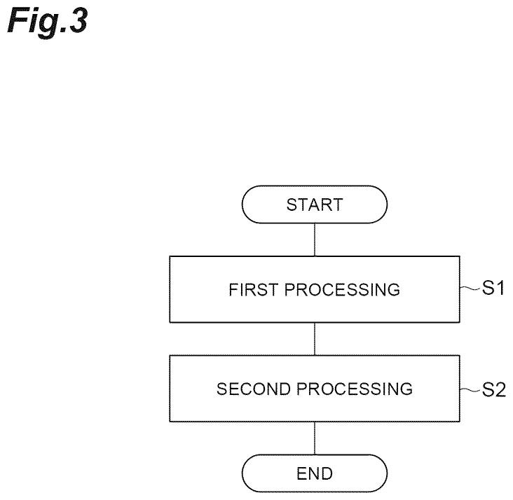

FIG. 3 to FIG. 5 are flowcharts illustrating an image processing method. As illustrated in FIG. 3, the image processing method includes a first processing step S1, and a subsequent second processing step S2. The CNN training unit 15 trains the CNN in the first processing step, and continuously trains the CNN also in the second processing step.

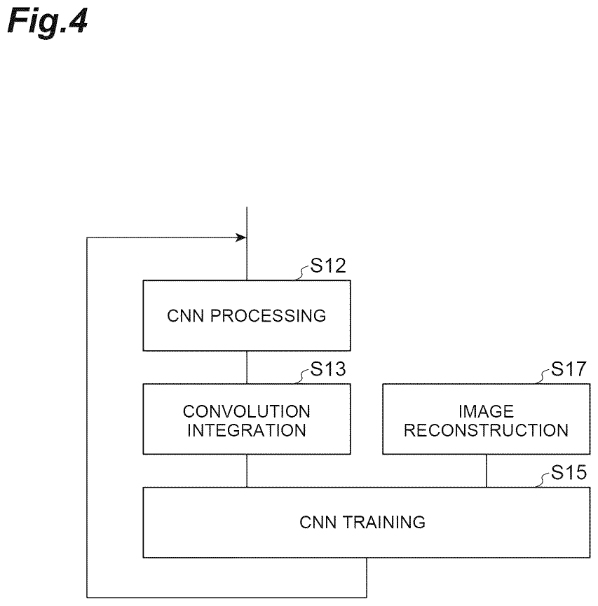

As illustrated in FIG. 4, the first processing step S1 includes an image reconstruction step S17 performed by the image reconstruction unit 17, a CNN processing step S12 performed by the CNN processing unit 12, a convolution integration step S13 performed by the convolution integration unit 13, and a CNN training step S15 performed by the CNN training unit 15.

In the image reconstruction step S17, the reconstructed image is created by using the general image reconstruction method. In the CNN processing step S12, the three-dimensional input image 20 is input to the CNN, and the three-dimensional output image 22 is created by the CNN. In the convolution integration step S13, the convolution integration of the point spread function is performed on the three-dimensional output image 22 created in the CNN processing step S12 to create the new three-dimensional output image 23.

In the CNN training step S15, the evaluation function including the error evaluation term representing the evaluation value related to the error between the reconstructed image created in the image reconstruction step S17 and the three-dimensional output image 23 created in the convolution integration step S13 is used, and the CNN is trained based on the error evaluation result. In the first processing step S1, the respective processes of the CNN processing step S12, the convolution integration step S13, and the CNN training step S15 are repeatedly performed a plurality of times.

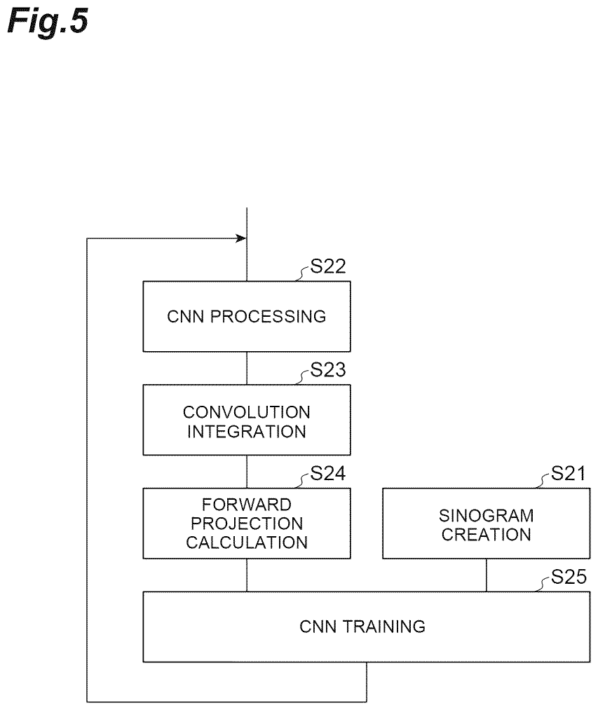

As illustrated in FIG. 5, the second processing step S2 includes a sinogram creation step S21 performed by the sinogram creation unit 11, a CNN processing step S22 performed by the CNN processing unit 12, a convolution integration step S23 performed by the convolution integration unit 13, a forward projection calculation step S24 performed by the forward projection calculation unit 14, and a CNN training step S25 performed by the CNN training unit 15.

In the sinogram creation step S21, the measured sinograms 21₁ to 21_{K} divided into the K blocks are created based on the coincidence information collected by the radiation tomography apparatus 2. In the CNN processing step S22, the three-dimensional input image 20 is input to the CNN, and the three-dimensional output image 22 is created by the CNN. In the convolution integration step S23, the convolution integration of the point spread function is performed on the three-dimensional output image 22 created in the CNN processing step S22 to create the new three-dimensional output image 23.

In the forward projection calculation step S24, the forward projection calculation is performed on the three-dimensional output image 23 to create the calculated sinograms 24₁ to 24_{K} divided into the K blocks. In the CNN training step S25, the error between the measured sinogram 21ₖ and the calculated sinogram 24ₖ is evaluated for each of the K blocks, and the CNN is trained based on the error evaluation result for each of the K blocks.

In the second processing step S2, the three-dimensional output image 22 which is created in the CNN processing step S22, after the respective processes of the CNN processing step S22, the convolution integration step S23, the forward projection calculation step S24, and the CNN training step S25 are repeatedly performed a plurality of times, is set as the three-dimensional tomographic image of the subject. The three-dimensional output image 23 which is created in the convolution integration step S23 may be set as the three-dimensional tomographic image of the subject. In addition, the convolution integration step S23 may not be provided.

Next, in the second processing step, the processing content of each of the steps in the image processing method in the case in which the sinogram is not divided into the plurality of blocks will be described. In the image processing method in the case in which the sinogram is not divided into the blocks, the processing is performed on the entire sinogram of each of the measured sinogram and the calculated sinogram.

Hereinafter, the processing by the CNN is set to f, the three-dimensional input image 20 which is input to the CNN is set to z, and a weight coefficient parameter representing a training state of the CNN is set to θ. As the training of the CNN progresses, θ changes. In the case in which the three-dimensional input image z is input to the CNN with the weight coefficient of θ, the three-dimensional output image 22 which is output from the CNN is set to x. The three-dimensional output image x is represented by the following Formula (1). In the CNN processing step, the processing represented by the following Formula is performed to create the three-dimensional output image x.

$$\begin{matrix}[ Formula 1 ] & \\ x = f ( θ \vert z ) & ( 1 )\end{matrix}$$

In the convolution integration step, the convolution integration of the point spread function is performed on the three-dimensional output image x which is created in the CNN processing step, and the new three-dimensional output image x is created. In addition, in FIG. 1, the three-dimensional output image x after the convolution integration is performed is denoted by PSF(f(θ|z)).

In the forward projection calculation step, the forward projection calculation is performed on the three-dimensional output image x to create the calculated sinogram 24. The calculated sinogram 24 is set to y, and a projection matrix for performing the forward projection calculation (Radon transform) from the three-dimensional output image x to the calculated sinogram y is set to P. The projection matrix is also referred to as a system matrix or a detection probability. The processing performed in the forward projection calculation step is represented by the following Formula (2).

$$\begin{matrix}[ Formula 2 ] & \\ y = P x & ( 2 )\end{matrix}$$

In the CNN training step in the second processing step, the measured sinogram 21 is set to y₀, the error between the measured sinogram y₀ and the calculated sinogram y (the above Formula (2)) is evaluated, and the CNN is trained based on the error evaluation result. The processing performed in the CNN training step is represented by the following Formula (3). A constrained optimization problem represented by the following Formula is a problem of optimizing the CNN parameter θ such that a value of an evaluation function E (y;y₀) becomes small, under the constraint that the three-dimensional output image x which is created by the CNN is the tomographic image of the subject.

$$\begin{matrix}[ Formula 3 ] & \\ min E ( y ; {y}_{0} ) & ( 3 )\end{matrix}$$

$$s . t . x = f ( θ \vert z )$$

The constrained optimization problem represented by the above Formula (3) can be rewritten as an unconstrained optimization problem represented by the following Formula (4). The evaluation function E is set to an arbitrary function, and for example, a L1 norm, a L2 norm, a negative log likelihood in a Poisson distribution, or the like can be used. In the case in which the L2 norm is used as the evaluation function, the following Formula (4) can be rewritten as the following Formula (5).

$$\begin{matrix}[ Formula 4 ] & \\ min E ( P f ( θ \vert z ) - {y}_{0} ) & ( 4 )\end{matrix}$$

$$\begin{matrix}[ Formula 5 ] & \\ {θ}^{*} = {arg min}_{θ} ‖ ( Pf ( θ \vert z ) - {y}_{0} ) ‖ & ( 5 )\end{matrix}$$

$${x}^{*} = f ( {θ}^{*} \vert z )$$

When the arrangement of the plurality of detectors provided in the radiation tomography apparatus is considered, there may be a region in which the collection of the coincidence information is impossible in the sinogram space. In consideration of the above fact, an optimization problem represented by the following Formula (6) may be used in place of the optimization problem represented by the above Formula (5). In the following Formula (6), m is a binary mask function, and has a value of 1 in a region in which the collection of the coincidence information is possible in the sinogram space, and has a value of 0 in a region in which the collection of the coincidence information is impossible. The following Formula (6) is a formula to selectively evaluate the error in the region in the sinogram space in which the collection of the coincidence information is possible by taking a Hadamard product of an error (y−y₀) and the binary mask function m.

$$\begin{matrix}[ Formula 6 ] & \\ {θ}^{*} = {arg min}_{θ} ‖ ( Pf ( θ \vert z ) - {y}_{0} ) ⊙ m ‖ & ( 6 )\end{matrix}$$

In the second processing step, by repeatedly performing the respective processes of the CNN processing step, the convolution integration step, the forward projection calculation step, and the CNN training step the plurality of times, and solving the above optimization problem for the CNN parameter θ, the calculated sinogram y approaches the measured sinogram y₀, and the three-dimensional output image x which is created by the CNN approaches the tomographic image of the subject.

Next, in the second processing step, the processing content of each of the steps in the image processing method in the case in which the sinogram is divided into the blocks will be described in detail. In the case in which the sinogram is divided into the blocks, in the forward projection calculation step, the forward projection calculation is performed on the three-dimensional output image x to create the calculated sinograms 24₁ to 24_{K} which are divided into the K blocks.

The calculated sinogram 24ₖ of the k-th block is set to yₖ, and the projection matrix for performing the forward projection calculation (Radon transform) from the three-dimensional output image x to the calculated sinogram yₖ is set to Pₖ. The processing performed in the forward projection calculation step is represented by the following Formula (7).

$$\begin{matrix}[ Formula 7 ] & \\ {y}_{k} = {P}_{k} x ( k = 1 , 2 , 3 , … , K ) & ( 7 )\end{matrix}$$

In the CNN training step in the second processing step, the measured sinogram 21ₖ of the k-th block is set to y₀ₖ, the error between the measured sinogram y₀ₖ and the calculated sinogram yₖ is evaluated for each of the K blocks, and the CNN is trained based on the error evaluation result for each of the K blocks.

The processing performed in the CNN training step is represented by an unconstrained optimization problem of the following Formula (8). In the case in which the L2 norm is used as the evaluation function, the following Formula (8) can be rewritten as the following Formula (9). Further, in the case in which the error is selectively evaluated in the region in the sinogram space in which the collection of the coincidence information is possible, it is represented by an unconstrained optimization problem of the following Formula (10). mₖ is a binary mask function in the k-th block.

$$\begin{matrix}[ Formula 8 ] & \\ min E ( {P}_{k} f ( θ \vert z ) - {y}_{0 k} ) & ( 8 )\end{matrix}$$

$$\begin{matrix}[ Formula 9 ] & \\ {θ}^{*} = {arg min}_{θ} ‖ ( {P}_{k} f ( θ \vert z ) - {y}_{0 k} ) ‖ ( k = 1 , 2 , 3 , … , K ) & ( 9 )\end{matrix}$$

$${x}^{*} = f ( {θ}^{*} \vert z )$$

$$\begin{matrix}[ Formula 10 ] & \\ {θ}^{*} = {arg min}_{θ} ‖ ( {P}_{k} f ( θ \vert f ) - {y}_{0 k} ) ⊙ {m}_{k} ‖ ( k = 1 , 2 , 3 , … , K ) & ( 10 )\end{matrix}$$

In the second processing step, by repeatedly performing the respective processes of the CNN processing step, the convolution integration step, the forward projection calculation step, and the CNN training step the plurality of times, and solving the above optimization problem for the CNN parameter θ, the calculated sinogram yₖ for each of the K blocks approaches the measured sinogram y₀ₖ, and the three-dimensional output image x which is created by the CNN approaches the tomographic image of the subject.

Next, the comparison between the case in which the sinogram is not divided into the blocks and the case in which the sinogram is divided into the blocks regarding the storage capacity required for storing the data in the RAM of the GPU will be described.

In general, the GPU is used in the processing by using the CNN. The GPU is an operation processing device specialized for the image processing, and includes the operation unit and the RAM which are integrated on one semiconductor chip. Various types of data used in the operation processing by the operation unit of the GPU are required to be stored in the RAM of the GPU.

The data to be stored in the RAM of the GPU includes, for example, the CNN input image, the CNN output image, the weight coefficient representing the training state of the CNN, a feature map, the measured sinogram, the calculated sinogram, a parameter necessary for performing the forward projection calculation, and the like, and requires an enormous storage capacity. However, the capacity of the RAM of the GPU is limited, and thus, in the image processing method as described above, the two-dimensional forward projection calculation can be performed, and on the other hand, it may be difficult to perform the three-dimensional forward projection calculation.

In this case, the number of pixels of the three-dimensional output image which is created by the CNN is set to 128×128×64, and the number of pixels of the sinogram space is set to 128×128×64× 19. In the image processing method in the case in which the sinogram is divided into the blocks, it is set to K=16, and the forward projection calculation is performed on the three-dimensional output image to create the calculated sinograms 24₁ to 24₁₆ which are equally divided into 16 blocks.

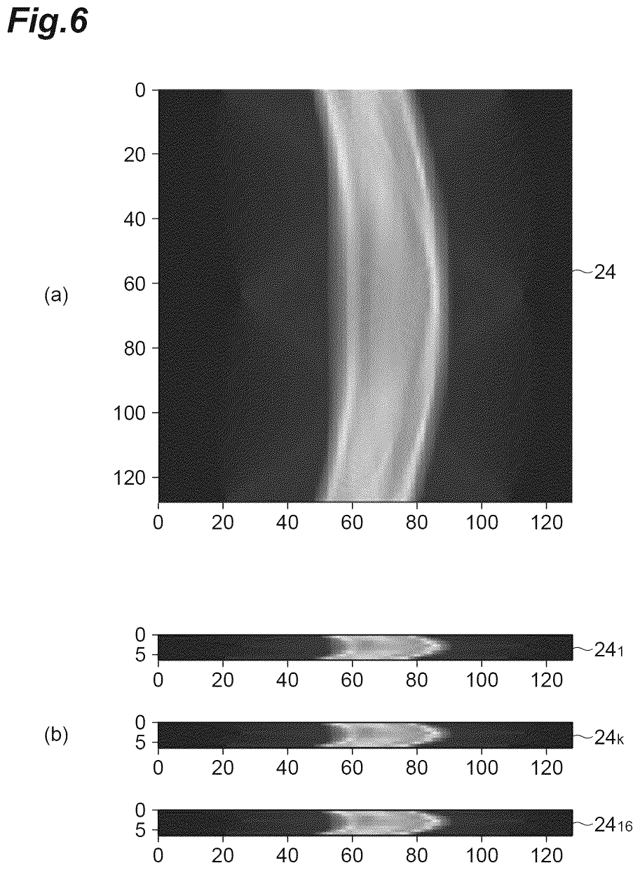

FIG. 6 includes diagrams showing respective examples of the calculated sinogram 24 in the case in which the block division is not performed and the calculated sinograms 24₁ to 24₁₆ in the case in which the block division is performed in comparison with each other. (a) in FIG. 6 is a diagram schematically showing the calculated sinogram 24 in the case in which the block division is not performed. (b) in FIG. 6 is a diagram schematically showing the calculated sinograms 24₁ to 24₁₆ in the case in which the block division is performed.

The number of pixels of the calculated sinogram 24ₖ of each of the blocks in the case in which the block division is performed is 128×8×64×19, which is 1/16 of the number of pixels of the calculated sinogram 24 in the case in which the block division is not performed. Further, the number of elements of the projection matrix Pₖ for performing the forward projection calculation from the three-dimensional output image to the calculated sinogram 24ₖ of the k-th block in the case in which the block division is performed is 1/16 of the number of elements of the projection matrix P for performing the forward projection calculation from the three-dimensional output image to the calculated sinogram 24 in the case in which the block division is not performed.

In the case in which the block division is performed, the storage capacity necessary for storing the data used at the time of performing the forward projection calculation can be reduced as compared with the case in which the block division is not performed, and it is possible to store the above data in the RAM of the GPU. Therefore, in the case in which the block division is performed, it becomes easy to perform the three-dimensional forward projection calculation from the CNN output image to the calculated sinogram, and the three-dimensional tomographic image of the subject can be easily created by training the CNN based on the evaluation result of the error between the calculated sinogram and the measured sinogram.

Next, the evaluation function which is used by the CNN training unit 15 in the CNN training step will be further described. In the above description, the evaluation function used in the first processing step is set to the evaluation function including only the error evaluation term representing the evaluation value related to the error between the reconstructed image created by the image reconstruction unit 17 and the output image created by the convolution integration unit 13. Further, the evaluation function used in the second processing step is set to the evaluation function including only the error evaluation term representing the evaluation value related to the error between the measured sinogram y₀ and the calculated sinogram y (=Pf(θ|z)).

In addition, in each of the first processing step and the second processing step, it is preferable to use the evaluation function which includes also a regularization term in addition to the error evaluation term. The regularization term is a term for suppressing the overtraining of the CNN, and represents an evaluation value related to a difference of pixel values between adjacent pixels in the output image.

That is, the evaluation function in the case in which the sinogram is not divided into the blocks is set to the following Formula (11) in place of the above Formula (5). Further, the evaluation function in the case in which the sinogram is divided into the blocks is set to the following Formula (12) in place of the above Formula (9).

$$\begin{matrix}[ Formula 11 ] & \\ {θ}^{*} = {arg min}_{θ} ‖ ( {P}_{k} f ( θ \vert z ) - {y}_{0} ) ‖ + β \cdot R ( f ( θ \vert z ) ) & ( 11 )\end{matrix}$$

$${x}^{*} = f ( {θ}^{*} \vert z )$$

$$\begin{matrix}[ Formula 12 ] & \\ {θ}^{*} = {arg min}_{θ} ‖ ( {P}_{k} f ( θ \vert z ) - {y}_{0 k} ) ‖ + β \cdot R ( f ( θ \vert z ) ) ( k = 1 , 2 , 3 , … , K ) & ( 12 )\end{matrix}$$

$${x}^{*} = f ( {θ}^{*} \vert z )$$

In the above Formulas, a first term on the right side is the error evaluation term, and a second term on the right side is the regularization term. The above regularization term penalizes the difference of the pixel values between the adjacent pixels in the output image. β is a hyperparameter for adjusting the degree of the effect of regularization. The smaller the value of β, the smaller the effect of regularization. The larger the value of β, the larger the effect of regularization (that is, the effect of suppression of the overtraining of the CNN).

The regularization term may represent the evaluation value related to the difference of the pixel values between the adjacent pixels in the output image 22 (f(θ|z)) which is output from the CNN processing unit 12, or may represent the evaluation value related to the difference of the pixel values between the adjacent pixels in the output image 23 (PSF(f(θ|z))) which is output from the convolution integration unit 13.

In the case in which the two-dimensional image is used, pixels adjacent to a certain pixel include pixels adjacent to the certain pixel in two directions orthogonal to each other, and further, preferably also include pixels adjacent to the certain pixel in diagonal directions. In the case of the two-dimensional image, the number of pixels adjacent to the certain pixel is 8, excluding pixels located at the edge or the corner of the image.

In the case in which the three-dimensional image is used, pixels adjacent to a certain pixel include pixels adjacent to the certain pixel in three directions orthogonal to each other, and further, preferably also include pixels adjacent to the certain pixel in diagonal directions. In the case of the three-dimensional image, the number of pixels adjacent to the certain pixel is 26, excluding pixels located at the edge or the corner of the image.

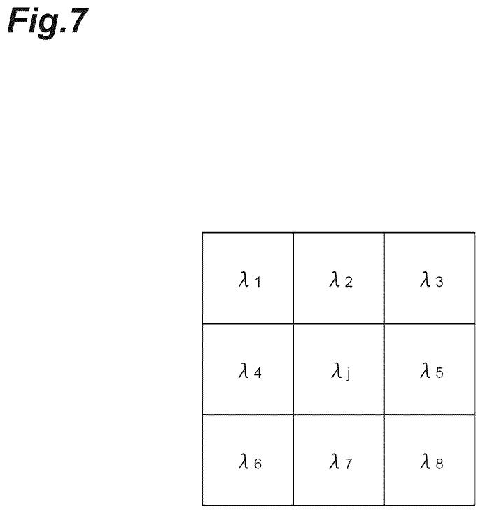

FIG. 7 is a diagram for describing the adjacent pixels in the output image. In this diagram, the output image is illustrated as the two-dimensional image, and 3×3 pixels in the image are illustrated. In this diagram, when a pixel value of the pixel located at the center is set to λⱼ and a pixel value of each of the eight pixels adjacent to the center pixel is set to λₖ (k=1 to 8), the difference of the pixel values between the adjacent pixels with respect to the center pixel described above is represented by |λⱼ−λₖ|. The regularization term represents the evaluation value related to the difference of the pixel values for all combinations of the adjacent pixels in the output image.

The regularization term is a term for representing the evaluation value related to the difference of the pixel values between the adjacent pixels in the output image, and may be represented by using various formulas. For example, the regularization term is represented by the following Formula (13). In the following Formula (13), Nⱼ represents a set of the pixels k adjacent to the pixel j. γ represents the magnitude of the change of the value of the regularization term with respect to the change of the pixel value λⱼ. The following Formula (13) includes a term of a difference of the pixel values of the adjacent pixels in a numerator, and includes a term of a sum of the pixel values of the adjacent pixels in a denominator, and thus, it represents the evaluation value relating to a relative difference of the pixel values between the adjacent pixels in the output image.

$$\begin{matrix}[ Formula 13 ] & \\ R ( f ( θ \vert z ) ) = {\sum }_{j} {\sum }_{k ∈ {N}_{j}} \frac{{( {λ}_{j} - {λ}_{k} )}^{2}}{( {λ}_{j} + {λ}_{k} ) - γ \vert {λ}_{j} - {λ}_{k} \vert} & ( 13 )\end{matrix}$$

In addition, Formula (13) is similar to a formula described in Non Patent Document 2. However, in Non Patent Document 2, the formula similar to Formula (13) is used in the processing of reconstructing the tomographic image of the subject based on the coincidence information collected by using the PET apparatus, and the formula is not used in performing the noise reduction processing for the tomographic image by using the DIP technique.

Further, as the regularization term, for example, Gibbs prior (Non Patent Document 3), total variation (Non Patent Document 4), or the like may also be used. In addition, the above documents also describe a technique for performing the reconstruction processing of the tomographic image of the subject, and do not describe a technique for performing the noise reduction processing for the tomographic image by using the DIP technique.

Next, the result obtained by creating simulation data by using a Monte Carlo simulation of a head PET apparatus using a digital brain phantom image, and reconstructing the tomographic image by using each of first and second image processing methods using the simulation data will be described.

In the first image processing method of a comparative example, the tomographic image was reconstructed by performing only the second processing step without performing the first processing step. In the second image processing method of an example, the tomographic image was reconstructed by performing the second processing step following the first processing step. In each of the first and second image processing methods, in the second processing step, each of the measured sinogram and the calculated sinogram was divided into the plurality of blocks, and the CNN was trained by using the evaluation function including only the error evaluation term without including the regularization term.

As the phantom image, a three-dimensional image which is prepared by using a brain image which is obtained from Brain Web (https://brainweb.bic.mni.mcgill.ca/brainweb/), and further, embedding a simulated tumor in a white matter portion of the brain image, was used. The number of pixels of the phantom image was set to 128×128×64. The number of pixels in the sinogram space was set to 128×128×64×19, and the sinogram space was equally divided into two blocks. The error evaluation term of the evaluation function was set to a mean squared error (MSE). A three-dimensional random noise image was used as the input image input to the CNN.

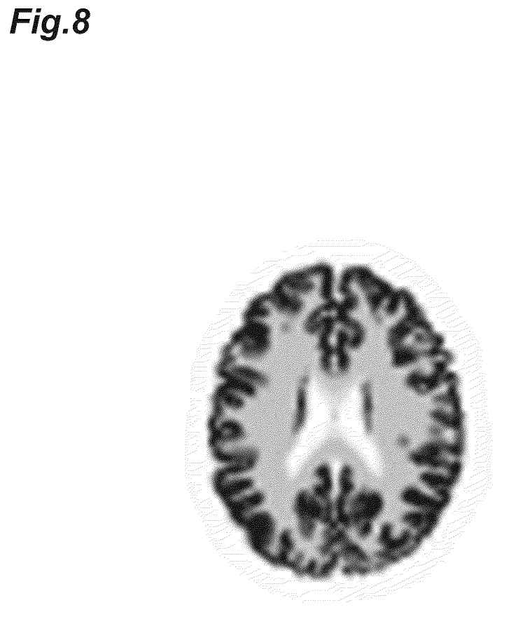

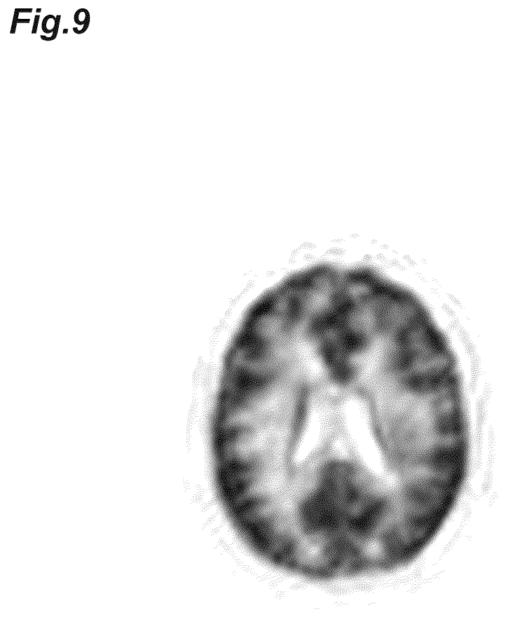

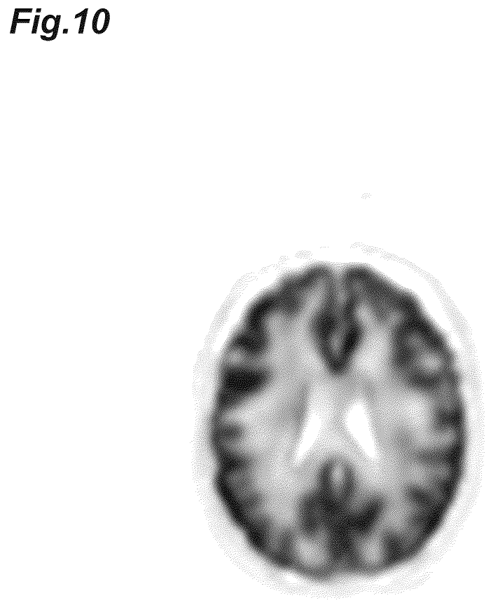

FIG. 8 is a diagram showing the original image (correct image) of the tomographic image of the brain. FIG. 9 is a diagram showing the tomographic image of the brain obtained by using the first image processing method. FIG. 10 is a diagram showing the tomographic image of the brain obtained by using the second image processing method.

The PSNR of the tomographic image (FIG. 9) obtained by the first image processing method is 20.70 dB, and the PSNR of the tomographic image (FIG. 10) obtained by the second image processing method is 21.60 dB. The peak signal to noise ratio (PSNR) is a value representing the quality of the image in decibels (dB), and the higher value means the better image quality.

As described above, as compared with the first image processing method, in the second image processing method, the PSNR of the tomographic image is higher, and the noise reduction performance is excellent. Further, as compared with the first image processing method, in the second image processing method, the structure of the gray matter can be reconstructed in greater detail.

In the first image processing method, the number of repetitions in the second processing step is 11, and a required time is about 165 minutes. In the second image processing method, a required time for the first processing step is several minutes, the number of repetitions in the second processing step is 3, and a required time for the second processing step is about 45 minutes. As described above, as compared with the first image processing method, in the second image processing method, the required time is about one third.

As described above, as compared with the first image processing method in which only the second processing step is performed, in the second image processing method in which the first processing step and the subsequent second processing step are performed, it is confirmed that the tomographic image in which noise is further reduced can be obtained in a shorter time.

In the present embodiment, by performing the training of the CNN in a short time to some extent in the first processing step, and then further performing the training of the CNN in the subsequent second processing step, it is possible to shorten the required time for the overall processing including the required time for the second processing step, and in addition, it is possible to obtain the tomographic image in which noise is reduced.

The image processing apparatus and the image processing method are not limited to the embodiments and configuration examples described above, and various modifications are possible.

The image processing apparatus of a first aspect according to the above embodiment is an image processing apparatus for creating a tomographic image of a subject based on coincidence information collected by a radiation tomography apparatus including a plurality of detectors arranged around a measurement space in which the subject into which an RI source is injected is placed, and includes (1) an image reconstruction unit for creating a reconstructed image by using an analytical image reconstruction method or a statistical image reconstruction method based on the coincidence information collected by the radiation tomography apparatus; (2) a sinogram creation unit for creating a sinogram based on the coincidence information collected by the radiation tomography apparatus; (3) a CNN processing unit for inputting an input image to a convolutional neural network, and creating an output image by the convolutional neural network; (4) a forward projection calculation unit for performing forward projection calculation on the output image to create a sinogram; and (5) a CNN training unit for training the convolutional neural network, and (6) in a first processing step, (a) the CNN training unit uses an evaluation function including an error evaluation term representing an evaluation value related to an error between the reconstructed image and the output image, and trains the convolutional neural network based on a value of the evaluation function, and (b) respective processes of the CNN processing unit and the CNN training unit are repeatedly performed a plurality of times, and (7) in a second processing step following the first processing step, (a) the CNN training unit uses an evaluation function including an error evaluation term representing an evaluation value related to an error between the sinogram created by the sinogram creation unit and the sinogram created by the forward projection calculation unit, and trains the convolutional neural network based on a value of the evaluation function, and (b) the output image after respective processes of the CNN processing unit, the forward projection calculation unit, and the CNN training unit are repeatedly performed a plurality of times is set as the tomographic image of the subject.

In the image processing apparatus of a second aspect, in the configuration of the first aspect, the sinogram creation unit may create the sinogram divided into a plurality of blocks based on the coincidence information collected by the radiation tomography apparatus, the forward projection calculation unit may perform the forward projection calculation on the output image to create the sinogram divided into the plurality of blocks, and in the second processing step, the CNN training unit may train the convolutional neural network based on the value of the evaluation function for each of the plurality of blocks.

In the image processing apparatus of a third aspect, in the configuration of the first or second aspect, each of the tomographic image, the reconstructed image, the input image, and the output image may be a three-dimensional image.

In the image processing apparatus of a fourth aspect, in the configuration of any one of the first to third aspects, the apparatus may further include a convolution integration unit for performing convolution integration of a point spread function on the output image, and the forward projection calculation unit may perform the forward projection calculation on the output image after a process of the convolution integration unit is performed.

In the image processing apparatus of a fifth aspect, in the configuration of any one of the first to fourth aspects, in the second processing step, the CNN training unit may evaluate the error by using the error evaluation term in a region in a sinogram space in which collection of the coincidence information by the radiation tomography apparatus is possible.

In the image processing apparatus of a sixth aspect, in the configuration of any one of the first to fifth aspects, the CNN training unit may use the evaluation function further including a regularization term representing an evaluation value related to a difference of pixel values between adjacent pixels in the output image, and may train the convolutional neural network based on the value of the evaluation function.

In the image processing apparatus of a seventh aspect, in the configuration of any one of the first to sixth aspects, the CNN processing unit may input an image representing morphological information of the subject to the convolutional neural network as the input image.

In the image processing apparatus of an eighth aspect, in the configuration of any one of the first to sixth aspects, the CNN processing unit may input an MRI image of the subject to the convolutional neural network as the input image.

In the image processing apparatus of a ninth aspect, in the configuration of any one of the first to sixth aspects, the CNN processing unit may input a CT image of the subject to the convolutional neural network as the input image.

In the image processing apparatus of a tenth aspect, in the configuration of any one of the first to sixth aspects, the CNN processing unit may input a static PET image of the subject to the convolutional neural network as the input image.

In the image processing apparatus of an eleventh aspect, in the configuration of any one of the first to sixth aspects, the CNN processing unit may input a random noise image to the convolutional neural network as the input image.

The radiation tomography system according to the above embodiment includes a radiation tomography apparatus including a plurality of detectors arranged around a measurement space in which a subject into which an RI source is injected is placed, and for collecting coincidence information; and the image processing apparatus having the above configuration and for creating the tomographic image of the subject based on the coincidence information collected by the radiation tomography apparatus.

The image processing method of a first aspect according to the above embodiment is an image processing method for creating a tomographic image of a subject based on coincidence information collected by a radiation tomography apparatus including a plurality of detectors arranged around a measurement space in which the subject into which an RI source is injected is placed, and includes (1) an image reconstruction step of creating a reconstructed image by using an analytical image reconstruction method or a statistical image reconstruction method based on the coincidence information collected by the radiation tomography apparatus; (2) a sinogram creation step of creating a sinogram based on the coincidence information collected by the radiation tomography apparatus; (3) a CNN processing step of inputting an input image to a convolutional neural network, and creating an output image by the convolutional neural network; (4) a forward projection calculation step of performing forward projection calculation on the output image to create a sinogram; and (5) a CNN training step of training the convolutional neural network, and (6) in a first processing step, (a) in the CNN training step, an evaluation function including an error evaluation term representing an evaluation value related to an error between the reconstructed image and the output image is used, and the convolutional neural network is trained based on a value of the evaluation function, and (b) respective processes of the CNN processing step and the CNN training step are repeatedly performed a plurality of times, and (7) in a second processing step following the first processing step, (a) in the CNN training step, an evaluation function including an error evaluation term representing an evaluation value related to an error between the sinogram created in the sinogram creation step and the sinogram created in the forward projection calculation step is used, and the convolutional neural network is trained based on a value of the evaluation function, and (b) the output image after respective processes of the CNN processing step, the forward projection calculation step, and the CNN training step are repeatedly performed a plurality of times is set as the tomographic image of the subject.

In the image processing method of a second aspect, in the configuration of the first aspect, in the sinogram creation step, the sinogram divided into a plurality of blocks may be created based on the coincidence information collected by the radiation tomography apparatus, in the forward projection calculation step, the forward projection calculation may be performed on the output image to create the sinogram divided into the plurality of blocks, and in the second processing step, in the CNN training step, the convolutional neural network may be trained based on the value of the evaluation function for each of the plurality of blocks.

In the image processing method of a third aspect, in the configuration of the first or second aspect, each of the tomographic image, the reconstructed image, the input image, and the output image may be a three-dimensional image.

In the image processing method of a fourth aspect, in the configuration of any one of the first to third aspects, the method may further include a convolution integration step of performing convolution integration of a point spread function on the output image, and in the forward projection calculation step, the forward projection calculation may be performed on the output image after a process of the convolution integration step is performed.

In the image processing method of a fifth aspect, in the configuration of any one of the first to fourth aspects, in the second processing step, in the CNN training step, the error may be evaluated by using the error evaluation term in a region in a sinogram space in which collection of the coincidence information by the radiation tomography apparatus is possible.

In the image processing method of a sixth aspect, in the configuration of any one of the first to fifth aspects, in the CNN training step, the evaluation function further including a regularization term representing an evaluation value related to a difference of pixel values between adjacent pixels in the output image may be used, and the convolutional neural network may be trained based on the value of the evaluation function.

In the image processing method of a seventh aspect, in the configuration of any one of the first to sixth aspects, in the CNN processing step, an image representing morphological information of the subject may be input to the convolutional neural network as the input image.

In the image processing method of an eighth aspect, in the configuration of any one of the first to sixth aspects, in the CNN processing step, an MRI image of the subject may be input to the convolutional neural network as the input image.

In the image processing method of a ninth aspect, in the configuration of any one of the first to sixth aspects, in the CNN processing step, a CT image of the subject may be input to the convolutional neural network as the input image.

In the image processing method of a tenth aspect, in the configuration of any one of the first to sixth aspects, in the CNN processing step, a static PET image of the subject may be input to the convolutional neural network as the input image.

In the image processing method of an eleventh aspect, in the configuration of any one of the first to sixth aspects, in the CNN processing step, a random noise image may be input to the convolutional neural network as the input image.

### INDUSTRIAL APPLICABILITY

The present invention can be used as an image processing apparatus and an image processing method capable of reducing the number of CNN training epochs by using a DIP technique and obtaining a tomographic image in which noise is reduced in a short time, when creating the tomographic image of a subject by training a CNN based on an evaluation result of an error between a calculated sinogram and a measured sinogram.

### REFERENCE SIGNS LIST

1—radiation tomography system, 2—radiation tomography apparatus, 10—image processing apparatus, 11—sinogram creation unit, 12—CNN processing unit, 13—convolution integration unit, 14—forward projection calculation unit, 15—CNN training unit, 16—storage unit, 17 image reconstruction unit.

1. An image processing apparatus for creating a tomographic image of a subject based on coincidence information collected by a radiation tomography apparatus including a plurality of detectors arranged around a measurement space in which the subject into which an RI source is injected is placed, the image processing apparatus comprising:
an image reconstruction unit configured to create a reconstructed image by using an analytical image reconstruction method or a statistical image reconstruction method based on the coincidence information collected by the radiation tomography apparatus;
a sinogram creation unit configured to create a sinogram based on the coincidence information collected by the radiation tomography apparatus;
a CNN processing unit configured to input an input image to a convolutional neural network, and create an output image by the convolutional neural network;
a forward projection calculation unit configured to perform forward projection calculation on the output image to create a sinogram; and
a CNN training unit configured to train the convolutional neural network, wherein
in a first processing step,
the CNN training unit is configured to use an evaluation function including an error evaluation term representing an evaluation value related to an error between the reconstructed image and the output image, and train the convolutional neural network based on a value of the evaluation function, and
respective processes of the CNN processing unit and the CNN training unit are repeatedly performed a plurality of times, and
in a second processing step following the first processing step,
the CNN training unit is configured to use an evaluation function including an error evaluation term representing an evaluation value related to an error between the sinogram created by the sinogram creation unit and the sinogram created by the forward projection calculation unit, and train the convolutional neural network based on a value of the evaluation function, and
the output image after respective processes of the CNN processing unit, the forward projection calculation unit, and the CNN training unit are repeatedly performed a plurality of times is set as the tomographic image of the subject.

2. The image processing apparatus according to claim 1,
wherein the sinogram creation unit is configured to create the sinogram divided into a plurality of blocks based on the coincidence information collected by the radiation tomography apparatus,
the forward projection calculation unit is configured to perform the forward projection calculation on the output image to create the sinogram divided into the plurality of blocks, and
in the second processing step, the CNN training unit is configured to train the convolutional neural network based on the value of the evaluation function for each of the plurality of blocks.

3. The image processing apparatus according to claim 1, wherein each of the tomographic image, the reconstructed image, the input image, and the output image is a three-dimensional image.

4. The image processing apparatus according to claim 1, further comprising a convolution integration unit for performing configured to perform convolution integration of a point spread function on the output image, wherein
the forward projection calculation unit is configured to perform the forward projection calculation on the output image after a process of the convolution integration unit is performed.

5. The image processing apparatus according to claim 1, wherein in the second processing step, the CNN training unit evaluates is configured to evaluate the error by using the error evaluation term in a region in a sinogram space in which collection of the coincidence information by the radiation tomography apparatus is possible.

6. The image processing apparatus according to claim 1, wherein the CNN training unit is configured to use the evaluation function further including a regularization term representing an evaluation value related to a difference of pixel values between adjacent pixels in the output image, and train the convolutional neural network based on the value of the evaluation function.

7. The image processing apparatus according to claim 1, wherein the CNN processing unit is configured to input an image representing morphological information of the subject to the convolutional neural network as the input image.

8. The image processing apparatus according to claim 1, wherein the CNN processing unit is configured to input an MRI image of the subject to the convolutional neural network as the input image.

9. The image processing apparatus according to claim 1, wherein the CNN processing unit is configured to input a CT image of the subject to the convolutional neural network as the input image.

10. The image processing apparatus according to claim 1, wherein the CNN processing unit is configured to input a static PET image of the subject to the convolutional neural network as the input image.

11. The image processing apparatus according to claim 1, wherein the CNN processing unit is configured to input a random noise image to the convolutional neural network as the input image.

12. A radiation tomography system comprising:
a radiation tomography apparatus including a plurality of detectors arranged around a measurement space in which a subject into which an RI source is injected is placed, and configured to collect coincidence information; and
the image processing apparatus according to claim 1 configured to create the tomographic image of the subject based on the coincidence information collected by the radiation tomography apparatus.

13. An image processing method for creating a tomographic image of a subject based on coincidence information collected by a radiation tomography apparatus including a plurality of detectors arranged around a measurement space in which the subject into which an RI source is injected is placed, the image processing method comprising:
an image reconstruction step of creating a reconstructed image by using an analytical image reconstruction method or a statistical image reconstruction method based on the coincidence information collected by the radiation tomography apparatus;
a sinogram creation step of creating a sinogram based on the coincidence information collected by the radiation tomography apparatus;
a CNN processing step of inputting an input image to a convolutional neural network, and creating an output image by the convolutional neural network;
a forward projection calculation step of performing forward projection calculation on the output image to create a sinogram; and
a CNN training step of training the convolutional neural network, wherein
in a first processing step,
in the CNN training step, an evaluation function including an error evaluation term representing an evaluation value related to an error between the reconstructed image and the output image is used, and the convolutional neural network is trained based on a value of the evaluation function, and
respective processes of the CNN processing step and the CNN training step are repeatedly performed a plurality of times, and
in a second processing step following the first processing step,
in the CNN training step, an evaluation function including an error evaluation term representing an evaluation value related to an error between the sinogram created in the sinogram creation step and the sinogram created in the forward projection calculation step is used, and the convolutional neural network is trained based on a value of the evaluation function, and
the output image after respective processes of the CNN processing step, the forward projection calculation step, and the CNN training step are repeatedly performed a plurality of times is set as the tomographic image of the subject.

14. The image processing method according to claim 13, wherein
in the sinogram creation step, the sinogram divided into a plurality of blocks is created based on the coincidence information collected by the radiation tomography apparatus,
in the forward projection calculation step, the forward projection calculation is performed on the output image to create the sinogram divided into the plurality of blocks, and
in the second processing step, in the CNN training step, the convolutional neural network is trained based on the value of the evaluation function for each of the plurality of blocks.

15. The image processing method according to claim 13, wherein each of the tomographic image, the reconstructed image, the input image, and the output image is a three-dimensional image.

16. The image processing method according to claim 13, further comprising a convolution integration step of performing convolution integration of a point spread function on the output image, wherein
in the forward projection calculation step, the forward projection calculation is performed on the output image after a process of the convolution integration step is performed.

17. The image processing method according to claim 13, wherein in the second processing step, in the CNN training step, the error is evaluated by using the error evaluation term in a region in a sinogram space in which collection of the coincidence information by the radiation tomography apparatus is possible.

18. The image processing method according to claim 13, wherein in the CNN training step, the evaluation function further including a regularization term representing an evaluation value related to a difference of pixel values between adjacent pixels in the output image is used, and the convolutional neural network is trained based on the value of the evaluation function.

19. The image processing method according to claim 13, wherein in the CNN processing step, an image representing morphological information of the subject is input to the convolutional neural network as the input image.

20. The image processing method according to claim 13, wherein in the CNN processing step, an MRI image of the subject is input to the convolutional neural network as the input image.

21. The image processing method according to claim 13, wherein in the CNN processing step, a CT image of the subject is input to the convolutional neural network as the input image.

22. The image processing method according to claim 13, wherein in the CNN processing step, a static PET image of the subject is input to the convolutional neural network as the input image.

23. The image processing method according to claim 13, wherein in the CNN processing step, a random noise image is input to the convolutional neural network as the input image.
